(19) United States
(12) Patent Application Publication
(10) Pub. No.: US 2004/0070073 A1
(43) Pub. Date: Apr. 15, 2004

(54) Underfill gap enhancement

(76) Inventors: Shirish Shah, San Ramon, CA (US); Zafer S. Kutlu, Menlo Park, CA (US); Kumar Nagarajan, San Jose, CA (US)

Correspondence Address: LSI LOGIC CORPORATION, 1621 BARBER LANE, MS: D-106 LEGAL, MILPITAS, CA, 95035, US

(21) Appl. No.: 10/270,954

(22) Filed: Oct. 15, 2002

(51) Int. Cl. H01L 23/48

(52) U.S. Cl. 257/734

(57) ABSTRACT

A package substrate having pads for receiving an integrated circuit, where the improvement is the pads having a height of between about two mils and about three mils. In this manner, additional structures such as solder on the pads do not need to be added, and coined, in order to ensure a minimum gap between the package substrate and the monolithic integrated circuit. The pads may be formed of at least one of copper, nickel, and gold. Also described is a packaged integrated circuit having a package substrate with pads for receiving a monolithic integrated circuit, where the improvement is the pads having a height of between about two mils and about three mils. The monolithic integrated circuit is attached to the pads with solder bumps. Additionally described is a method of fabricating a package substrate, where the improvement is the step of forming pads on the package substrate to a thickness of between about two mils and about three mils, where the pads are adapted for receiving a monolithic integrated circuit. The pads are formed with a plating process. The monolithic integrated circuit is attached to the package substrate by reflowing the solder bumps between the contact pads of the monolithic integrated circuit and the pads of the package substrate, thereby forming a gap between the monolithic integrated circuit and the package substrate, which is under filled with an under fill material.

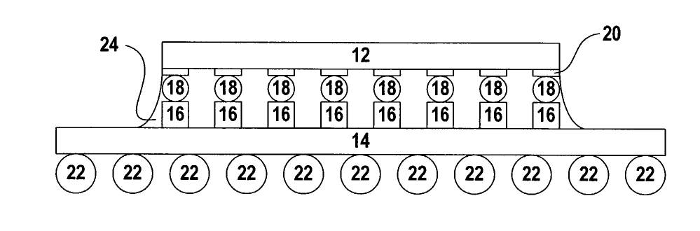

### FIELD

This invention relates to the field of integrated circuit fabrication. More particularly, this invention relates to mounting and packaging integrated circuits.

### BACKGROUND

Integrated circuits are typically packaged prior to use. Packaging the integrated circuit tends to provide several benefits. For example, the packaged integrated circuit is easier to handle, and the package tends to protect the integrated circuit from damage. Further, attaching the integrated circuit to other circuit components is more easily accomplished when the integrated circuit is packaged. However, packages for integrated circuits can also contribute to yield loss, as there may be problems during the packaging process.

For example, a flip chip integrated circuit is one in which the side of the integrated circuit on which the active circuitry and the bonding pads are disposed is mounted toward the package substrate. Typically, some type of electrically conductive material, such as solder bumps, is employed to electrically connect the bonding pads to the pads on the package substrate, and then an underfill material is dispensed in the gap formed between the integrated circuit and the package substrate by the solder bumps, to increase the structural strength of the packaged integrated circuit.

However, there can be problems when attempting to underfill the integrated circuit, for example, if the gap is not of sufficient size, then the underfill material tends to not flow uniformly under the integrated circuit, which leaves voids. This can weaken the mechanical connection between the integrated circuit and the package substrate, and create other problems. Therefore, processes have been developed to ensure a gap of a minimum distance between the integrated circuit and the package substrate.

One such process is a solder on pad package substrate. The electrical contacts on the package substrate are formed by screen printing solder on to the package substrate pads. The screen printed solder is then coined to planarized the solder and provide a suitable surface for the electrical attachment of the integrated circuit. Unfortunately, the coining process can damage the package substrate. In addition, as the pitch between bonding pads on the integrated circuit decreases with increasing device density, the limits of the screen printing process are challenged.

What is needed, therefore, is a method for ensuring a minimum distance between a package substrate and an attached integrated circuit, that does not require screen printing or coining.

### SUMMARY

The above and other needs are met by an improvement to a package substrate having pads for receiving an integrated circuit, where the improvement is the pads having a height of between about two mils and about three mils. In this manner, additional structures such as solder on the pads do not need to be added, and coined, in order to ensure a minimum gap between the package substrate and the monolithic integrated circuit. In various preferred embodiments, the pads are formed of at least one of copper, nickel, and gold. According to another aspect of the invention there is provided a packaged integrated circuit having a package substrate with pads for receiving a monolithic integrated circuit, where the improvement is the pads having a height of between about two mils and about three mils. The monolithic integrated circuit is preferably attached to the pads with solder bumps. Also described is a method of fabricating a package substrate, where the improvement is the step of forming pads on the package substrate to a thickness of between about two mils and about three mils, where the pads are adapted for receiving a monolithic integrated circuit. The pads are preferably formed with a plating process. Most preferably, the monolithic integrated circuit is attached to the package substrate by reflowing the solder bumps between the contact pads of the monolithic integrated circuit and the pads of the package substrate, thereby forming a gap between the monolithic integrated circuit and the package substrate, which is underfilled with an underfill material.

### BRIEF DESCRIPTION OF THE DRAWINGS

Further advantages of the invention are apparent by reference to the detailed description when considered in conjunction with the figure, which is not to scale so as to more clearly show the details, which depicts a monolithic integrated circuit mounted to a package substrate with tall metal pads.

### DETAILED DESCRIPTION

Referring now to the figure, there is depicted a packaged integrated circuit 10, where a monolithic integrated circuit 12 is mounted to a package substrate 14. The package substrate has pads 16 which are formed to a thickness of between about two mils and about three mils, and most preferably about three mils. The monolithic integrated circuit 12 has bonding pads 20, to which are attached solder bumps 18. The monolithic integrated circuit 12 is attached to the package substrate 14 by bringing it into contact with the pads 16 of the package substrate 14, and reflowing the solder bumps 18 between the bonding pads 20 of the monolithic integrated circuit 12 and the pads 16 of the package substrate 14. Thus, additional solder on pads of the package substrate 14 is not required, and neither is the potentially damaging coining process. The gap between the monolithic integrated circuit 12 is thus ensured to be a proper minimum distance, such as between about three mils and about four mils, and most preferably about four mils, and the underfill material 24 flows properly and completely between the monolithic integrated circuit 12 and the package substrate 14, because the pads 16 are formed to a height that is greater than normal.

The pads 16 are most preferably at least one of copper, nickel, and gold. The pads 16 may be formed by any deposition process that is compatible with the materials, processes, and structures described and implied herein, such as sputtering or evaporation. However, in a most preferred embodiment the pads 16 are formed with a plating process. Such processes as described herein are more able to produce pads 16 having the desired thickness than is a screen printing process. In addition, such processes as described are also more able to produce pads 16 having a finer pitch, as required by higher device density monolithic integrated circuits 12.

The foregoing description of preferred embodiments for this invention have been presented for purposes of illustration and description. They are not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as is suited to the particular use contemplated. All such modifications and variations are within the scope of the invention as determined by the appended claims when interpreted in accordance with the breadth to which they are fairly, legally, and equitably entitled.

What is claimed is:

1. In a package substrate having pads for receiving an integrated circuit, the improvement comprising the pads having a height of between about two mils and about three mils.

2. The package substrate of claim 1, wherein the pads are formed of at least one of copper, nickel, and gold.

3. A packaged integrated circuit having a monolithic integrated circuit attached to the package substrate of claim 1.

4. In a packaged integrated circuit having a package substrate with pads for receiving a monolithic integrated circuit, the improvement comprising the pads having a height of between about two mils and about three mils.

5. The packaged integrated circuit of claim 4, wherein the pads are formed of at least one of copper, nickel, and gold.

6. The packaged integrated circuit of claim 4, wherein the monolithic integrated circuit is attached to the pads with solder bumps.

7. In a method of fabricating a package substrate, the improvement comprising the step of forming pads on the package substrate to a thickness of between about two mils and about three mils.

8. The method of claim 7, wherein the pads are formed of at least one of copper, nickel, and gold.

9. The method of claim 7, wherein the pads are formed with a plating process.

10. The method of claim 7, further comprising the steps of:
attaching a monolithic integrated circuit to the package substrate by reflowing solder bumps between contact pads of the monolithic integrated circuit and the pads of the package substrate, thereby forming a gap between the monolithic integrated circuit and the package substrate, and
underfilling the gap between the monolithic integrated circuit and the package substrate with an underfill material.
